(19) United States
(12) Patent Application Publication
(10) Pub. No.: US 2026/0123485 A1
(43) Pub. Date: Apr. 30, 2026

(54) PACKAGE SUBSTRATE AND SEMICONDUCTOR PACKAGE INCLUDING THE SAME

(71) Applicant: Samsung Electronics Co., Ltd., Suwon-si (KR)

(72) Inventor: Jaejin Lee, Suwon-si (KR)

(21) Appl. No.: 19/252,482

(22) Filed: Jun. 27, 2025

(30) Foreign Application Priority Data
Oct. 31, 2024 (KR) 10-2024-0152223

(51) Int. Cl. H01L 23/498

(52) U.S. Cl. CPC H10W 70/65

(57) ABSTRACT

A package substrate includes an insulation layer having first and second surfaces opposite to each other in a vertical direction, a wiring on the first surface of the insulation layer, a pad which includes first conductive layers at opposite sides of the wiring on the first surface of the insulation layer, and a second conductive layer contacting upper surfaces of the first conductive layers, spaced apart from an upper surface of the wiring, and overlapping at least a portion of the wiring in the vertical direction and a protective layer contacting the first surface of the insulation layer, and covering a sidewall of the pad. The protective layer includes solder resist (SR).

### CROSS-REFERENCE TO RELATED APPLICATION

This application claims priority under 35 U.S.C. § 119 to Korean Patent Application No. 10-2024-0152223, filed on Oct. 31, 2024, in the Korean Intellectual Property Office, the contents of which are herein incorporated by reference in their entirety.

### FIELD

The present invention relates to package substrates and semiconductor packages including the same.

### BACKGROUND

A semiconductor package includes a package substrate and a semiconductor chip on the package substrate, and the package substrate includes wirings and pads disposed at a plurality of levels. A method of arranging the wirings and pads is needed.

### SUMMARY

Some embodiments define a package substrate having enhanced electrical characteristics.

Some embodiments define a semiconductor package having enhanced electrical characteristics.

According to some embodiments, there is a package substrate which may include an insulation layer having first and second surfaces opposite to each other in a vertical direction, a wiring on the first surface of the insulation layer, a pad including first conductive layers at opposite sides of the wiring on the first surface of the insulation layer, and a second conductive layer contacting upper surfaces of the first conductive layers, spaced apart from an upper surface of the first wiring, and overlapping at least a portion of the wiring in the vertical direction, and a protective layer contacting the first surface of the insulation layer and covering a sidewall of the pad. The protective layer may include solder resist (SR).

According to some embodiments, there is a package substrate which may include a insulation layer having first and second surfaces opposite to each other in a vertical direction, a wiring on the first surface of the insulation layer and extending in a first direction substantially parallel to the first surface of the insulation layer, and a pad including first conductive layers at opposite sides of the wiring on the first surface of the insulation layer in a second direction, which may be substantially parallel to the first surface of the insulation layer and crossing the first direction. Each of the first conductive layers may extend in the first direction, a second conductive layer may contact upper surfaces of the first conductive layers, extend in the first direction, and overlap the wiring in the vertical direction. A protective layer may be disposed on the first surface of the insulation layer, and contact a sidewall and an upper surface of the pad. The protective layer may have an opening partially exposing the upper surface of the pad and may include solder resist (SR).

According to some embodiments, there is a semiconductor package which may include a package substrate, a semiconductor chip, a first conductive connection member, and a second conductive connection member. The package substrate may include a first insulation layer having first and second surfaces opposite to each other in a vertical direction, a first wiring on the first surface of the first insulation layer, a pad, a first protective layer, a second insulating interlayer, a second wiring and a second protective layer. The pad may include first conductive layers at opposite sides of the first wiring on the first surface of the first insulation layer and a second conductive layer contacting upper surfaces of the first conductive layers, spaced apart from an upper surface of the first wiring, and overlapping at least a portion of the first wiring in the vertical direction. The first protective layer may contact the first surface of the first insulation layer, and cover a sidewall of the pad. The first protective layer may include solder resist (SR). A second insulation layer may be on the second surface of the first insulation layer. A second wiring may be in the second insulation layer. A second protective layer may be on the second insulation layer, cover an upper surface of the second wiring, and may have an opening exposing a portion of the lower surface of the second wiring. A semiconductor chip may be on the package substrate. A first conductive connection member may contact the exposed portion of the lower surface of the second wiring and an upper surface of the semiconductor chip. A second conductive connection member may contact an upper surface of the pad.

In the package substrate in accordance with some embodiments, the wiring at the same level as the pad may not detour the pad but may extend through the pad. Thus, the freedom of designing the pad and the wiring may increase, and the pad and the wiring may be arranged with a high density so that the package substrate may have high-speed operation characteristics.

### BRIEF DESCRIPTION OF THE DRAWINGS

FIG. 1 is a plan view illustrating a package substrate in accordance with some embodiments.

FIG. 2 is a cross-sectional view illustrating the package substrate of FIG. 1.

FIG. 3 is a plan view illustrating a method of manufacturing a package substrate in accordance with some embodiments.

FIG. 4 is a plan view illustrating a method of manufacturing a package substrate in accordance with some embodiments.

FIG. 5 is a cross-sectional view illustrating a method of manufacturing a package substrate in accordance with some embodiments.

FIG. 6 is a plan view illustrating a method of manufacturing a package substrate in accordance with some embodiments.

FIG. 7 is a cross-sectional view illustrating a method of manufacturing a package substrate in accordance with some embodiments.

FIG. 8 is a plan view illustrating a method of manufacturing a package substrate in accordance with some embodiments.

FIG. 9 is a cross-sectional view illustrating a method of manufacturing a package substrate in accordance with some embodiments.

FIG. 10 is a plan view illustrating a method of manufacturing a package substrate in accordance with some embodiments.

FIG. 11 is a cross-sectional view illustrating a method of manufacturing a package substrate in accordance with some embodiments.

FIG. 12 is a plan view illustrating a method of manufacturing a package substrate in accordance with some embodiments.

FIG. 13 is a cross-sectional view illustrating a method of manufacturing a package substrate in accordance with some embodiments.

FIG. 14 is a plan view illustrating a package substrate in accordance with some embodiments.

FIGS. 15 to 19 are plan views illustrating a method of manufacturing a package substrate in accordance with some embodiments.

FIGS. 20 to 22 are plan views illustrating package substrates in accordance with some embodiments.

FIG. 23 is a cross-sectional view illustrating a package substrate in accordance with some embodiments.

FIGS. 24 and 25 are plan views illustrating package substrates in accordance with some embodiments.

FIG. 26 is a cross-sectional view illustrating a semiconductor package in accordance with some embodiments.

### DETAILED DESCRIPTION

Hereinafter, some embodiments will be explained in detail with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

To clearly describe the present disclosure, description of some conventional elements or parts are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Likewise, when components are “immediately” adjacent to one another, no intervening components may be present. Further, in the specification, the word “on” or “above” may include on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

Spatially relative terms, such as “under,” “below,” “lower,” “over,” “upper”, etc., may be used herein for ease of description to describe one element or relationship of structures to another element or structure as illustrated in the drawings.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein. A first element that “covers” a second element may or may not be in contact with the second element.

Two directions substantially perpendicular to each other among horizontal directions that are substantially parallel to an upper surface of a package substrate may be referred to as first and second directions D1 and D2, respectively, and a direction substantially perpendicular to the upper surface of the package substrate may be referred to a third direction D3. Each of the first to third directions D1, D2 and D3 may include not only a direction shown in the drawings but also a direction inverse thereto.

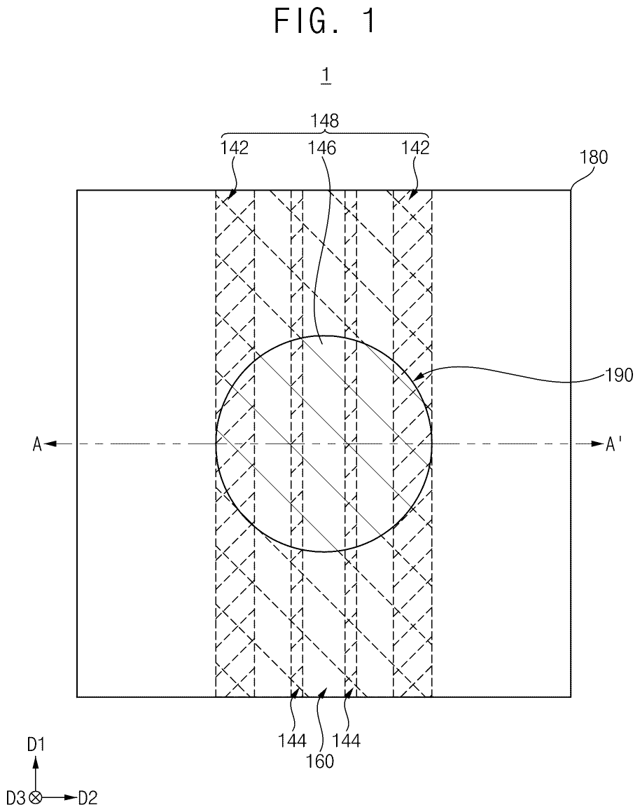

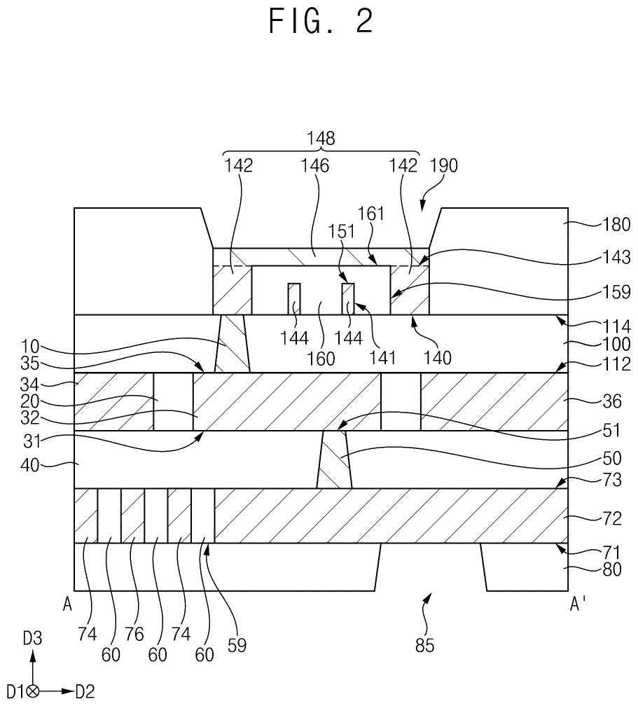

FIGS. 1 and 2 are a plan view and a cross-sectional view, respectively, illustrating a package substrate 1 in accordance with some embodiments. FIG. 2 is a cross-sectional view taken along line A-A′ of FIG. 1.

Referring to FIGS. 1 and 2, the package substrate 1 may include a first insulation layer 100 having first and second surfaces 112, 114 opposite to each other in the third direction D3, second to fourth insulation layers 20, 40, 60 sequentially stacked in the third direction D3 on the first surface 112 of the first insulation layer 100, first and second vias 10, 50 and first to sixth wirings 32, 34, 36, 72, 74, 76 in the first to fourth insulation layers 100, 20, 40, 60, and a first pad 148 and a second conductive layer 144 on the second surface 114 of the first insulation layer 100.

The package substrate 1 may further include a first protective layer 80 on a lower surface 59 of the fourth insulation layer 60, and a fifth insulation layer 160 and a second protective layer 180 on the second surface 114 of the first insulation layer 100.

Each of the first to fourth insulation layers 100, 20, 40, 60 may include an insulating material, e.g., polypropylene glycol (PPG), Ajinomoto build-up film (ABF), etc., and may also be referred to as a core.

The first and second vias 10, 50 may extend through the first and third insulation layers 100, 40, respectively. Each of the first to third wirings 32, 34, 36 may extend through the second insulation layer 20, and each of the fourth to sixth wirings 72, 74, 76 may extend through the fourth insulation layer 60. The first via 10 may contact a lower surface 140 of the first pad 148 and an upper surface 35 of the first wiring 32, and the second via 50 may contact a lower surface 31 of the first wiring 32 and an upper surface 73 of the fourth wiring 72.

In some embodiments, the first to third wirings 32, 34, 36 may serve as a signal wiring, a ground wiring and a power wiring, respectively, and the fourth to sixth wirings 72, 74, 76 may serve as a signal wiring, a ground wiring and a high-speed signal wiring, respectively, however, the inventive concept is not limited thereto. For example, the first to third wirings 32, 34, 36 may serve as a ground wiring, a signal wiring and a power wiring, respectively.

The first to sixth wirings 32, 34, 36, 72, 74, 76 and the first and second vias 10, 50 in the first to fourth insulation layers 100, 20, 40, 60 may be arranged in another layout that is different from that of FIGS. 1 and 2 and may perform other roles.

Each of the first and second vias 10, 50 and the first to sixth wirings 32, 34, 36, 72, 74, 76 may include a metal, e.g., copper, aluminum, tungsten, etc.

In some embodiments, the second conductive layer 144 may extend in the first direction D1 on the second surface 114 of the first insulation layer 100, and a plurality of second conductive layers 144 may be spaced apart from each other in the second direction D2. For example, two second conductive layers 144 may be spaced apart from each other in the second direction D2.

Each of the second conductive layers 144 may serve as a signal wiring, and thus may also be referred to as a seventh wiring 144.

The fifth insulation layer 160 may extend in the first direction D1 on the second surface 114 of the first insulation layer 100 and may cover the seventh wirings 144. That is, the fifth insulation layer 160 may cover a sidewall 141 and an upper surface 151 of each of the seventh wirings 144, and an upper surface 161 of the fifth insulation layer 160 may be higher than an upper surface 151 of each of the seventh wirings 144.

The first pad 148 may extend in the first direction D1 on the second surface 114 of the first insulation layer 100. In some embodiments, the first pad 148 may include first conductive layers 142 and a third conductive layer 146. Each of the first conductive layers 142 may extend in the first direction D1 on the second surface 114 of the first insulation layer 100. Each of the first conductive layers 142 may be at a side of a corresponding one of the seventh wirings 144 and may contact a sidewall 159 of the fifth insulation layer 160. An upper surface 143 of each of the first conductive layers 142 may be substantially coplanar with an upper surface 161 of the fifth insulation layer 160. In some embodiments, a width in the horizontal direction of each of the first conductive layers 142 may be substantially constant in the third direction D3.

The third conductive layer 146 may extend in the first direction D1 on the fifth insulation layer 160 and may contact the upper surfaces 143 of the first conductive layers 142 and the upper surface 161 of the fifth insulation layer 160. Thus, the first conductive layers 142 may surround sidewalls 141 of the seventh wirings 144 via the fifth insulation layer 160, and the third conductive layer 146 may cover upper surfaces 151 of the seventh wirings 144 via the fifth insulation layer 160. Thus, the third conductive layer 146 may overlap the seventh wirings 144 in the third direction D3. That is, the first pad 148 including the first and third conductive layers 142, 146 may have a shape of a tunnel that may cover the seventh wirings 144.

Each of the first to third conductive layers 142, 144, 146 may include a metal, e.g., copper, aluminum, tungsten, etc., and the fifth insulation layer 160 may include an inorganic insulating material or an organic insulating material.

The second protective layer 180 may be on the second surface 114 of the first insulation layer 100 and may cover the first pad 148. The second protective layer 180 may have a fifth opening 190 exposing a portion of the first pad 148. In some embodiments, the fifth opening 190 may have a shape of, e.g., a circle, an ellipse, a polygon, a polygon with rounded corners, etc., in a plan view, and FIG. 1 shows that the fifth opening 190 has a shape of a circle.

The first protective layer 80 may be on the lower surface 59 of the fourth insulation layer 60, and may cover the fourth to sixth wirings 72, 74, 76. The first protective layer 80 may have a first opening 85 exposing some of the fourth to sixth wirings 72, 74, 76, e.g., a lower surface 71 of the fourth wiring 72.

Each of the first and second protective layers 80, 180 may include an insulating material, e.g., solder resist (SR).

In some embodiments, the package substrate 1 may be a printed circuit board (PCB).

In the package substrate 1, the seventh wirings 144 may extend through the first pad 148 via the fifth insulation layer 160. That is, the seventh wirings 144 may be at the same level as the first pad 148, however, the seventh wirings 144 may not detour the first pad 148 but may extend through the first pad 148. Thus, when a plurality of first pads 148 and a plurality of seventh wirings 144 are at the same level, the seventh wirings 144 may not detour the first pads 148 so that the freedom of design of the first pads 148 and the seventh wirings 144 may increase and the first pads 148 and the seventh wirings 144 may be arranged with a high density. In other words, the seventh wirings 144 may go through the first pads 148. The seventh wirings 144 may go under the third conductive layer 146 and between two first conductive layers 142.

The third conductive layer 146 included in the first pad 148 and the first wiring 32 may be over and under, respectively, the seventh wiring 144, and thus, if both of the third conductive layer 146 and the first wiring 32 serve as ground wirings, the seventh wiring 144, the third conductive layer 146 and the first wiring 32 may form a strip line.

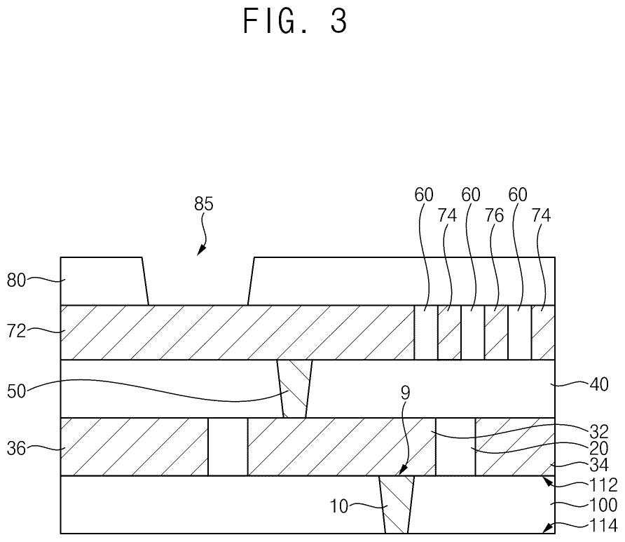

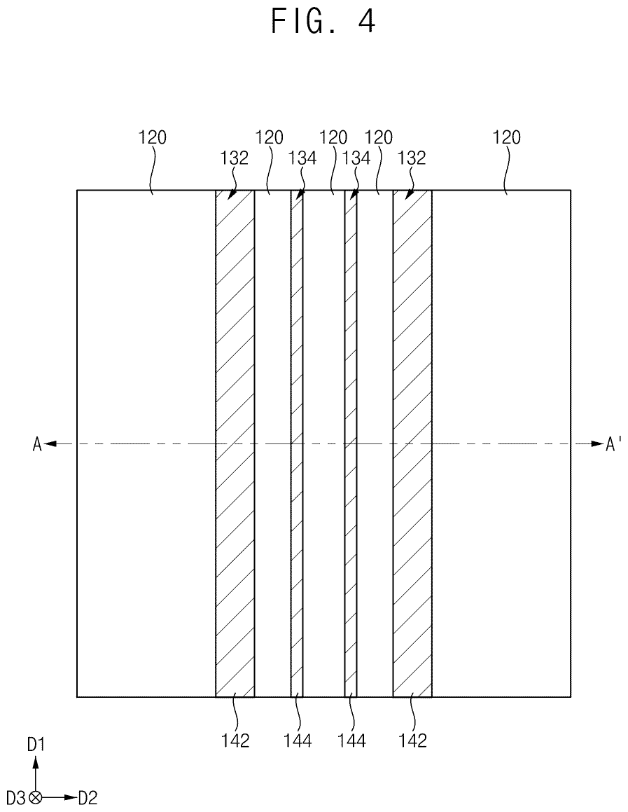

FIGS. 3 to 13 are plan views and cross-sectional views illustrating a method of manufacturing a package substrate 1 in accordance with some embodiments. FIGS. 4, 6, 8, 10, and 12 are the plan views, and FIGS. 3, 5, 7, 9, 11, and 13 are cross-sectional views taken along lines A-A′ of corresponding plan views, respectively. FIG. 3 may be oriented such that the partially manufactured package substrate 1 is rotated 180-degrees relative to the package substrate 1 in FIG. 2. Terms such as “upper” and “lower” may refer to the relative positions of components in the FIG. 2 orientation.

Referring to FIG. 3, a first via 10 extending through a first insulation layer 100 having first and second surfaces 112, 114 opposite to each other in the third direction D3 may be formed, a second insulation layer 20 may be formed on the first surface 112 of the first insulation layer 100 and the first via 10, and first to third wirings 32, 34, 36 extending through the second insulation layer 20 may be formed to be spaced apart from each other in the horizontal direction.

The first wiring 32 may contact a lower surface 9 of the first via 10.

A third insulation layer 40 may be formed on the second insulation layer 20 and the first to third wirings 32, 34, 36, a second via 50 extending through the third insulation layer 40 to contact a lower surface 31 of the first wiring 32 may be formed, a fourth insulation layer 60 may be formed on the third insulation layer 40 and the second via 50, and fourth to sixth wirings 72, 74, 76 extending through the fourth insulation layer 60 may be formed to be spaced apart from each other in the horizontal direction.

The fourth wiring 72 may contact a lower surface 51 of the second via 50.

A first protective layer 80 may be formed on the fourth insulation layer 60 and the fourth to sixth wirings 72, 74, 76, and may be partially removed to form a first opening 85 partially exposing a lower surface 71 of the fourth wiring 72.

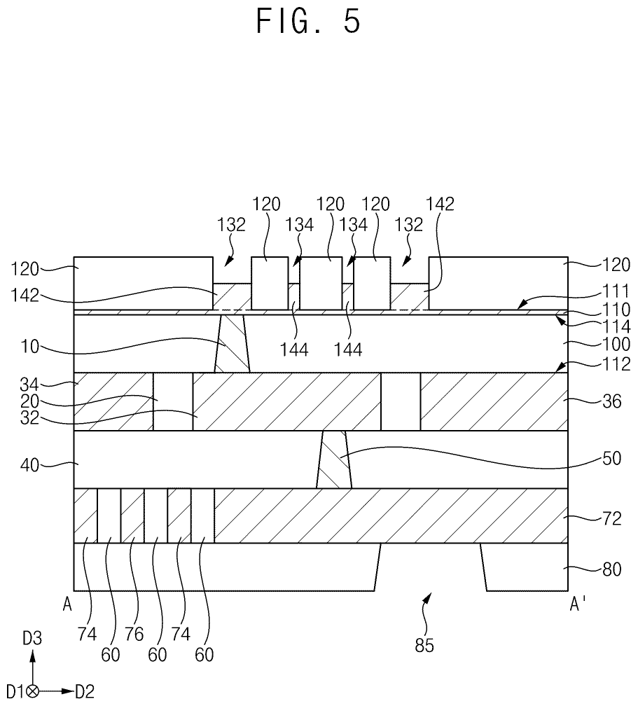

Referring to FIGS. 4 and 5, the first insulation layer 100 may be flipped so that the second surface 114 of the first insulation layer 100 may face upwardly, a seed layer 110 may be formed on the second surface 114 of the first insulation layer 100, a first mask 120 having second and third openings 132, 134 exposing an upper surface 111 of the seed layer 110 may be formed on the seed layer 110, and first and second conductive layers 142, 144 may be formed in the second and third openings 132, 134, respectively.

In some embodiments, the first mask 120 may include solder resist (SR).

In some embodiments, each of the second and third openings 132, 134 may extend in the first direction D1, and the second and third openings 132, 134 may be spaced apart from each other in the second direction D2. A width in the second direction D2 of the second opening 132 may be greater than a width in the second direction D2 of the third opening 134. In some embodiments, two third openings 134 may be formed to be adjacent to each other in the second direction D2, and second openings 132 may be formed at respective sides of the third openings 134 in the second direction D2.

The seed layer 110 may include a metal, e.g., copper. In some embodiments, the first and second conductive layers 142, 144 may be formed by an electroplating process or an electroless plating process and may be formed in lower portions of the second and third openings 132, 134, respectively. Each of the first and second conductive layers 142, 144 may include a metal, e.g., copper, and may be merged with the seed layer 110.

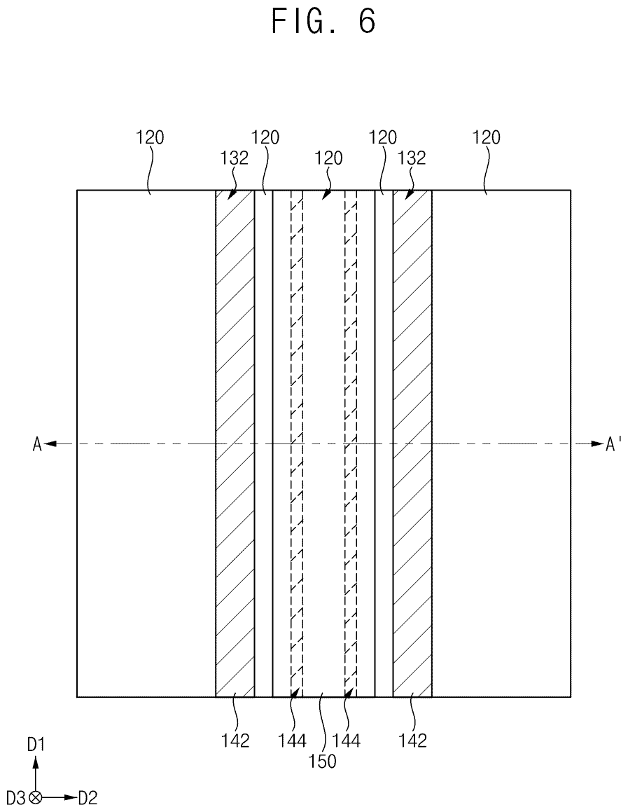

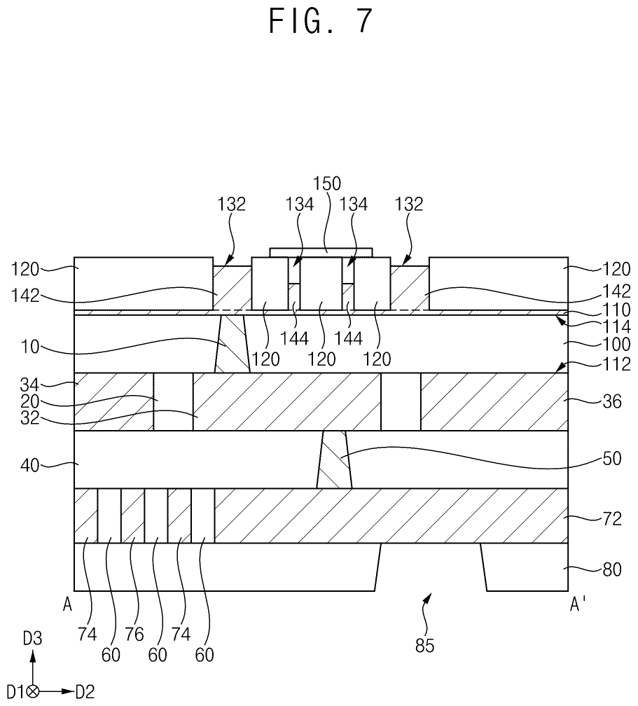

Referring to FIGS. 6 and 7, a second mask 150 may be on the first mask 120 to cover top ends of the third openings 134, and a first conductive layer 142 may be additionally formed in each of the second openings 132 by an electroplating process or an electroless plating process.

In some embodiments, the second mask 150 may extend in the first direction D1 and may be on the top ends of the third openings 134 and portions of the first mask 120 adjacent to the third openings 134 in the second direction D2. In some embodiments, the second mask 150 may include SR.

In some embodiments, as the additional first conductive layer 142 is formed in each of the second openings 132, an upper surface 143 of the first conductive layer 142 may be higher than an upper surface 151 of the second conductive layer 144 in each of the third openings 134.

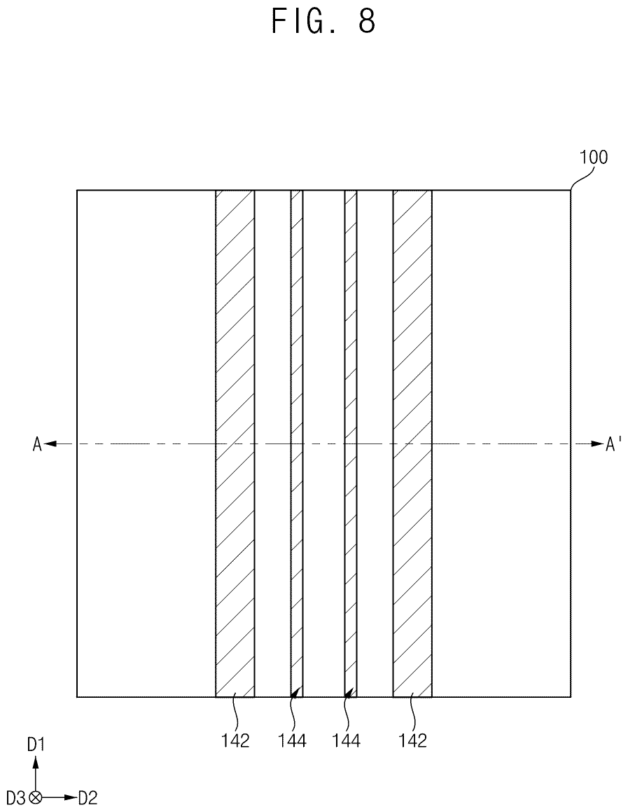

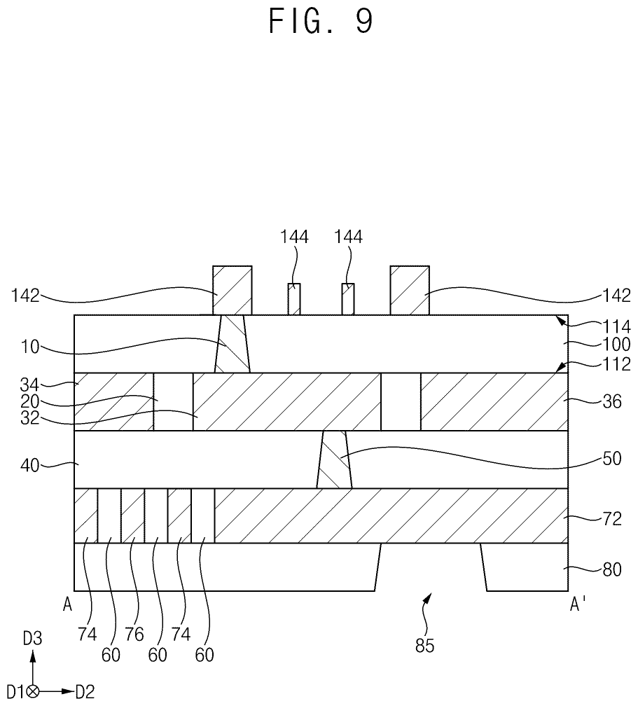

Referring to FIGS. 8 and 9, the first and second masks 120, 150 may be removed by, e.g., a stripping process, and an etching process may be performed on the first and second conductive layers 142, 144 and the seed layer 110.

Thus, all portions of the seed layer 110 except for a portion of the seed layer 110 under each of the first and second conductive layers 142, 144 may be removed.

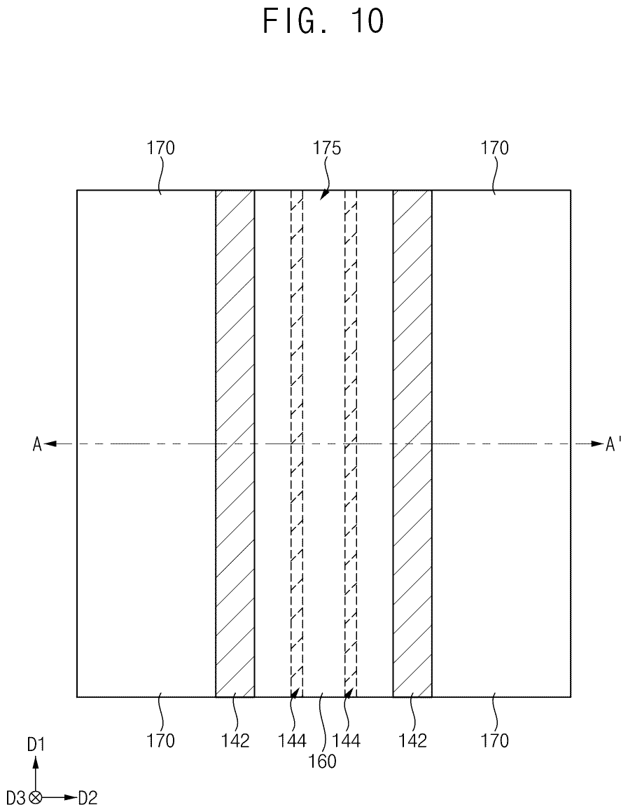

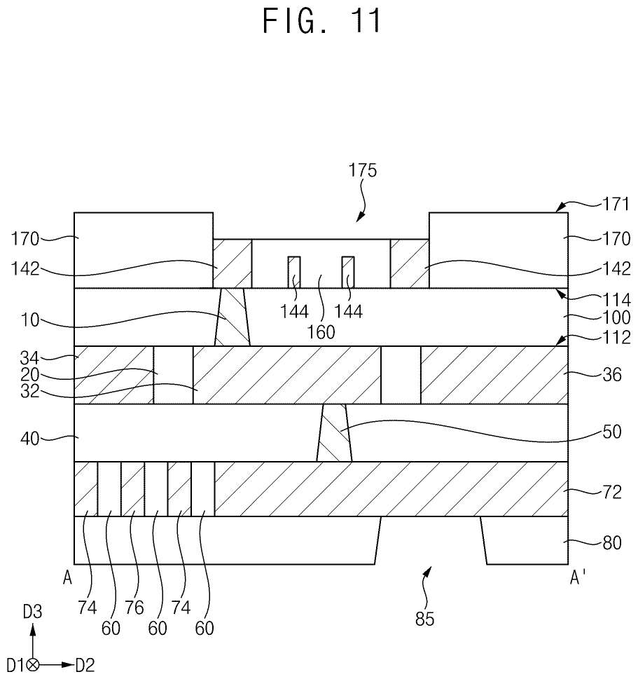

Referring to FIGS. 10 and 11, a fifth insulation layer 160 may be formed on the second surface 114 of the first insulation layer 100 to fill a space between the first conductive layers 142 and to cover the second conductive layers 144, and a third mask 170 may be formed on a portion of the second surface 114 of the first insulation layer 100 on which the first conductive layers 142 and the fifth insulation layer 160 are not formed.

In some embodiments, an upper surface 161 of the fifth insulation layer 160 may be substantially coplanar with an upper surface 143 of each of the first conductive layers 142, and an upper surface 171 of the third mask 170 may be higher than the upper surfaces 161, 143 of the fifth insulation layer 160 and the first conductive layers 142. Thus, a fourth opening 175 extending in the first direction D1 through the third mask 170 may be formed on the fifth insulation layer 160 and the first conductive layers 142.

In some embodiments, the third mask 170 may include SR.

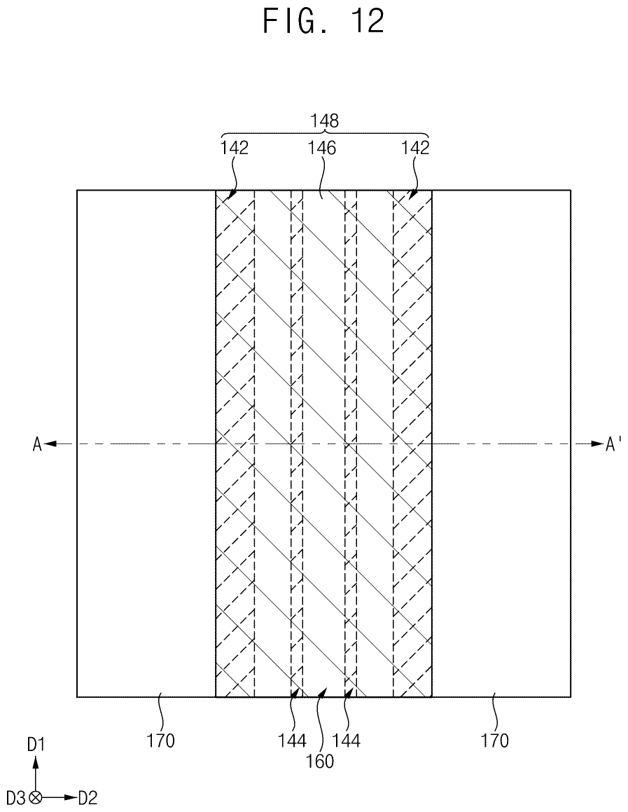

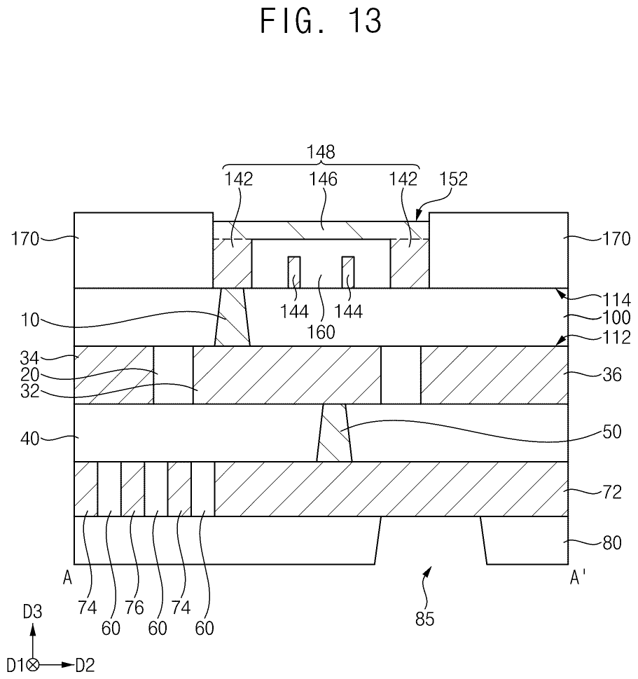

Referring to FIGS. 12 and 13, a third conductive layer 146 may be formed in the fourth opening 175 by an electroplating process or an electroless plating process.

In some embodiments, the third conductive layer 146 may include a metal, e.g., copper, and may be merged with the first conductive layers 142. The first and third conductive layers 142, 146 may form a first pad 148.

Referring back to FIGS. 1 and 2, the third mask 170 may be removed by, e.g., a stripping process, a second protective layer 180 may be formed on the second surface 114 of the first insulation layer 100 to cover the first pad 148, and the second protective layer 180 may be partially removed to form a fifth opening 190 exposing a portion of an upper surface 152 of the first pad 148.

In some embodiments, the fifth opening 190 may have a shape of, e.g., a circle, an ellipse, a polygon, a polygon with rounded corners, etc., in a plan view, and FIG. 1 shows that the fifth opening 190 has the shape of the circle.

The package substrate 1 may be manufactured by the above processes.

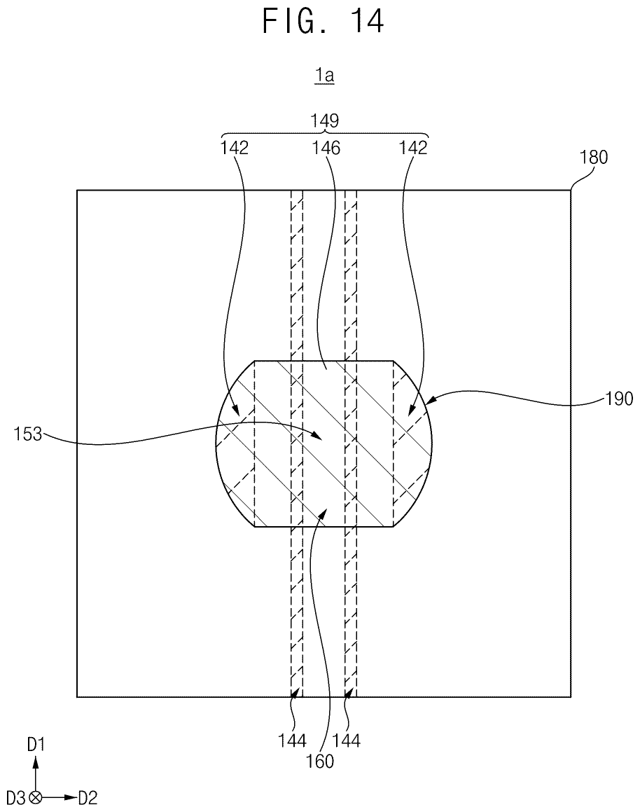

FIG. 14 is a plan view illustrating a package substrate 1a in accordance with some embodiments. This package substrate 1a may be substantially the same as or similar to that of FIGS. 1 and 2, except for including a second pad instead of the first pad, and thus repeated explanations are omitted herein.

Referring to FIG. 14, the package substrate 1a may include a second pad 149.

The second pad 149 may include the first conductive layers 142 and the third conductive layer 146, which may not extend in the first direction D1. Particularly, each of the first conductive layers 142 may have a shape of an arch in a plan view, and the fifth insulation layer 160 covering the seventh wirings 144 may be between the first conductive layers 142 to have a shape of a rectangle in a plan view.

The third conductive layer 146 may contact upper surfaces 143 of the first conductive layers 142 and the fifth insulation layer 160. Opposite sides in the first direction D1 of the third conductive layer 146 may have a shape of a line, while opposite sides in the second direction D2 of the third conductive layer 146 may have a convex curved line.

Thus, a portion of each of the seventh wirings 144 may extend through the second pad 149 via the fifth insulation layer 160, while other portions of each of the seventh wirings 144 may contact and by covered by the second protective layer 180. That is, the third conductive layer 146 included in the second pad 149 may overlap a portion of each of the seventh wirings 144 in the third direction D3.

The second protective layer 180 may be on the second surface 114 of the first insulation layer 100 and may cover the portion of each of the seventh wirings 144, and the fifth opening 190 may expose an upper surface 153 of the second pad 149.

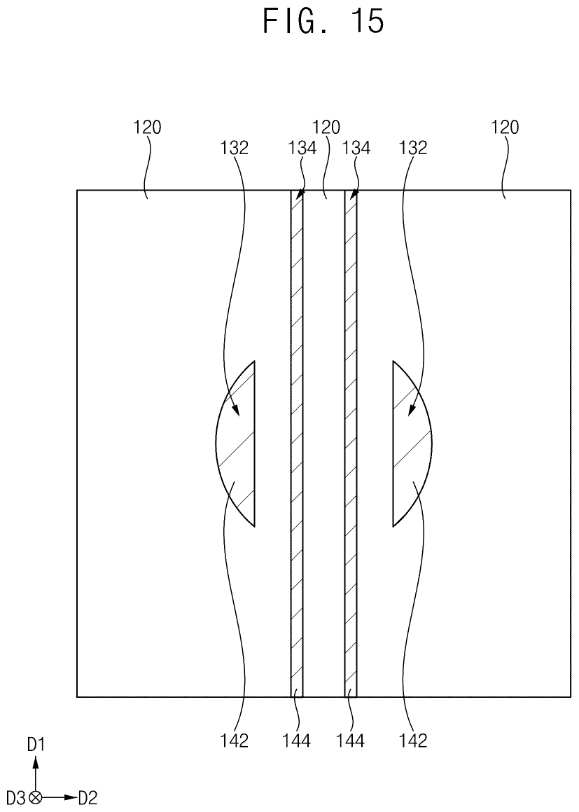

FIGS. 15 to 19 are plan views illustrating a method of manufacturing a package substrate 1a in accordance with some embodiments. This method may include processes substantially the same as or similar to those illustrated with respect to FIGS. 3 to 13 and FIGS. 1 and 2, and thus repeated explanations are omitted herein.

Referring to FIG. 15, processes substantially the same as or similar to those illustrated with respect to FIGS. 3 to 5 may be performed.

However, each of the second openings 132 may not extend in the first direction D1, but may have a shape of a portion of a circle in a plan view, and may be formed at each of opposite sides in the second direction D2 of the third openings 134. Thus, the second conductive layer 144 that may be formed in each of the third openings 134 may also have a shape of a portion of a circle in a plan view.

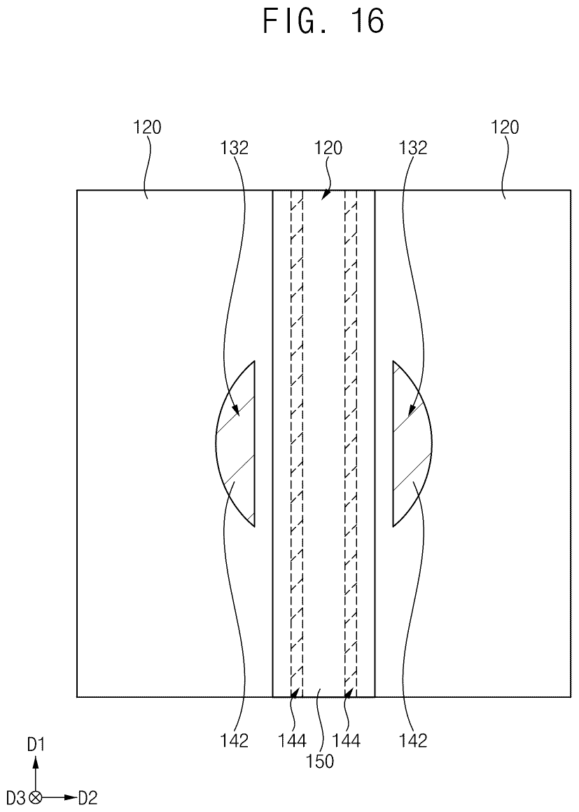

Referring to FIG. 16, processes substantially the same as or similar to those illustrated with respect to FIGS. 6 and 7 may be performed.

Thus, a second mask 150 may be on the first mask 120 to cover top ends of the third openings 134, and the first conductive layer 142 may be further formed in each of the second openings 132.

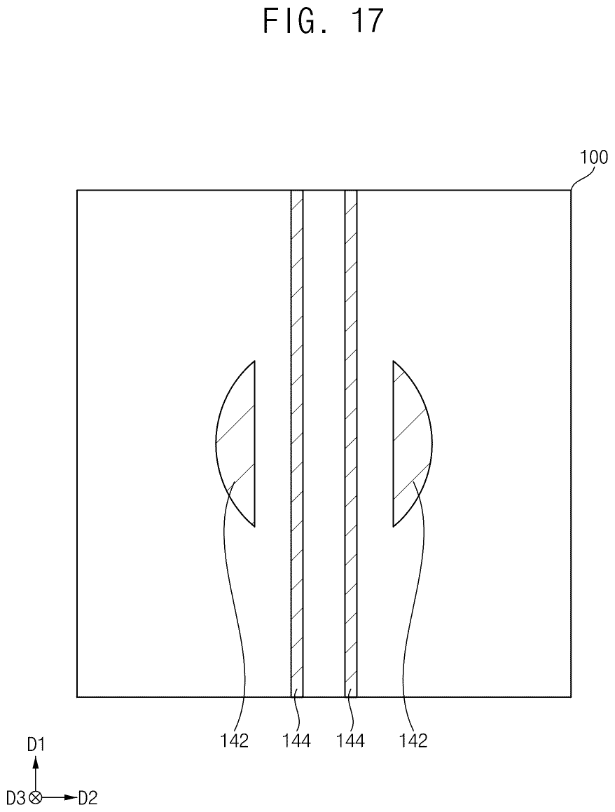

Referring to FIG. 17, processes substantially the same as or similar to those illustrated with respect to FIGS. 8 and 9 may be performed.

Thus, all portions of the seed layer 110 except for a portion of the seed layer 110 under the first and second masks 120, 150 and the first and second conductive layers 142, 144 may be removed.

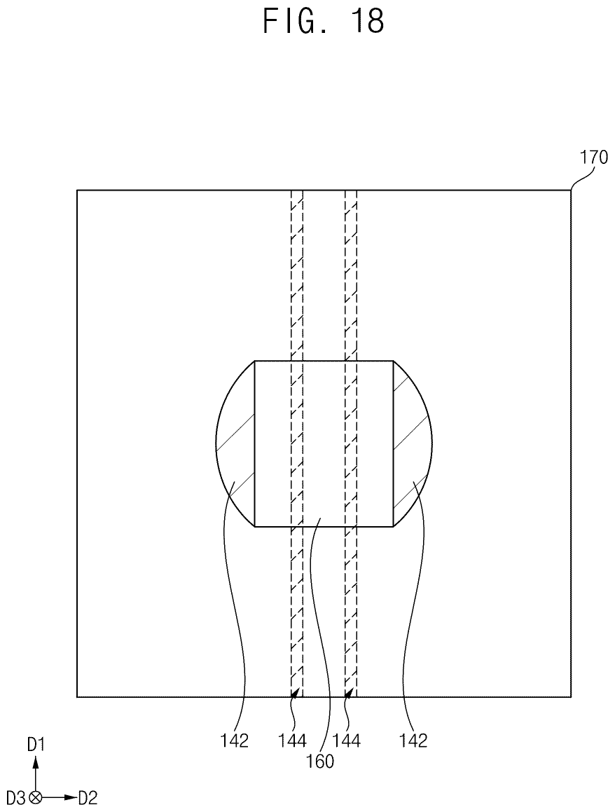

Referring to FIG. 18, processes substantially the same as or similar to those illustrated with respect to FIGS. 10 and 11 may be performed.

Thus, the fifth insulation layer 160 may be formed on the second surface 114 of the first insulation layer 100 to fill a space between the first conductive layers 142 and to cover the second conductive layers 144, and the third mask 170 may be formed on a portion of the second surface 114 of the first insulation layer 100 on which the first conductive layers 142 and the fifth insulation layer 160 are not formed.

As the second conductive layers 144 do not extend in the first direction D1, the fifth insulation layer 160 between the second conductive layers 144 may not extend in the first direction D1 and may have a shape of a rectangle in a plan view. The fourth opening 175 on the fifth insulation layer 160 and the first conductive layers 142 through the third mask 170 may also have a shape of, e.g., a rectangle, instead of extending in the first direction D1, in a plan view.

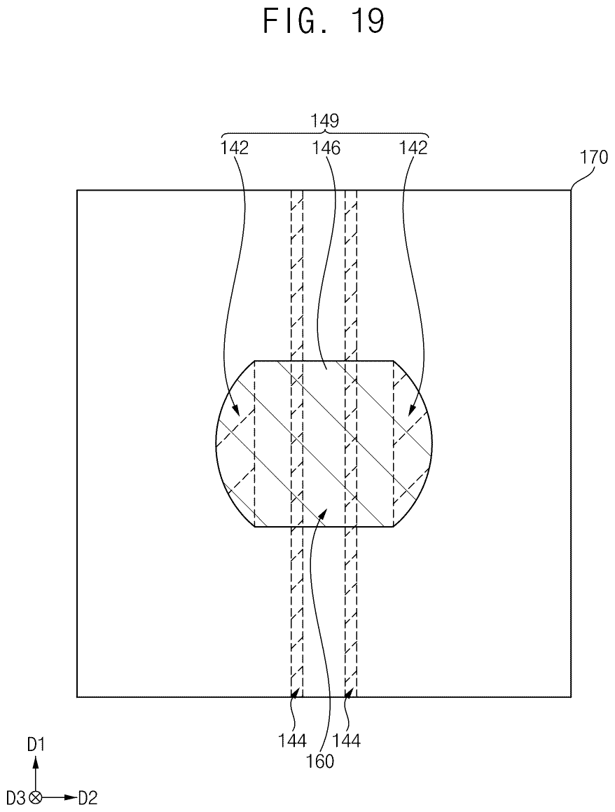

Referring to FIG. 19, processes substantially the same as or similar to those illustrated with respect to FIGS. 12 and 13 may be performed.

Thus, the third conductive layer 146 may be formed in the fourth opening 175, and may have a shape of, e.g., a rectangle in a plan view. The third conductive layer 146 and the first conductive layers 142 under the third conductive layer 146 may form a second pad 149.

Referring to FIG. 14, processes substantially the same as or similar to those illustrated with respect to FIGS. 1 and 2 may be performed to complete manufacturing the package substrate 1a.

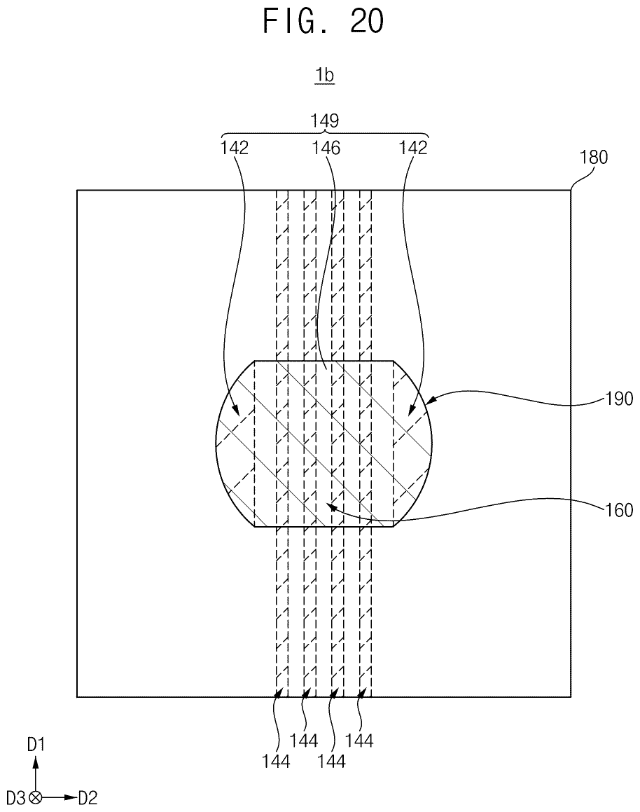

FIGS. 20 to 22 are plan views illustrating package substrates 1b, 1c, 1d in accordance with some embodiments, which may correspond to FIG. 14. These package substrates 1b, 1c, 1d may be substantially the same as or similar to those illustrated with respect to FIG. 14, except for the shapes and arrangements of the wirings, and thus repeated explanations are omitted herein.

Referring to FIG. 20, the package substrate 1b may include four seventh wirings 144, each of which may extend through second pad 149 via the fifth insulation layer 160, spaced apart from each other in the second direction D2.

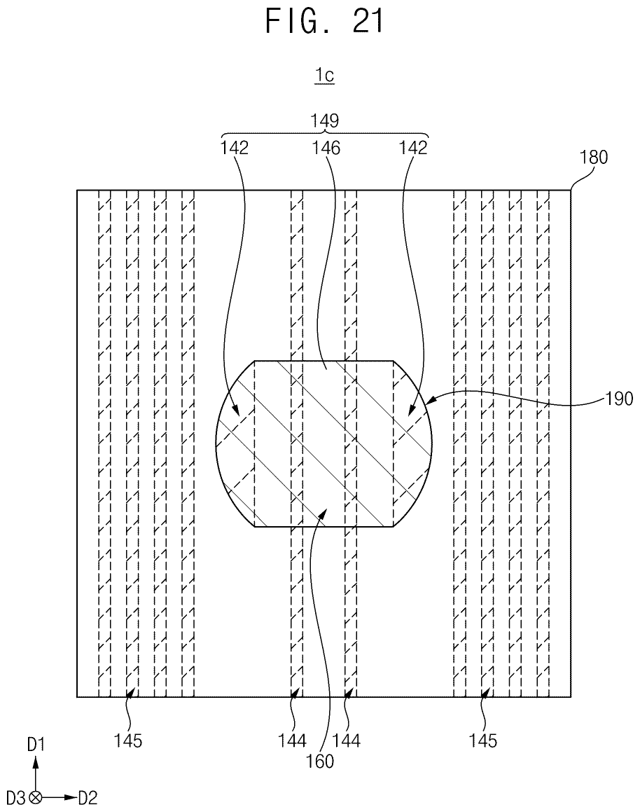

Referring to FIG. 21, the package substrate 1c may further include four eighth wirings 145, each of which may detour the second pad 149 and extend in the first direction D1, spaced apart from each other in the second direction D2 at each of opposite sides of the second pad 149 in the second direction D2. In other words, the package substrate 1c may further include eight eighth wirings 145 each of which may extend in the first direction D1 spaced apart from each other in the second direction D2. Four of the eight eighth wirings 145 and may be spaced apart from the second pad 149 in the second direction D2 on a first side of the second pad 149. The other four eighth wirings 145 may be spaced apart from the second pad 149 in the second direction D2 on a second side of the second pad 149 which is opposite the first side.

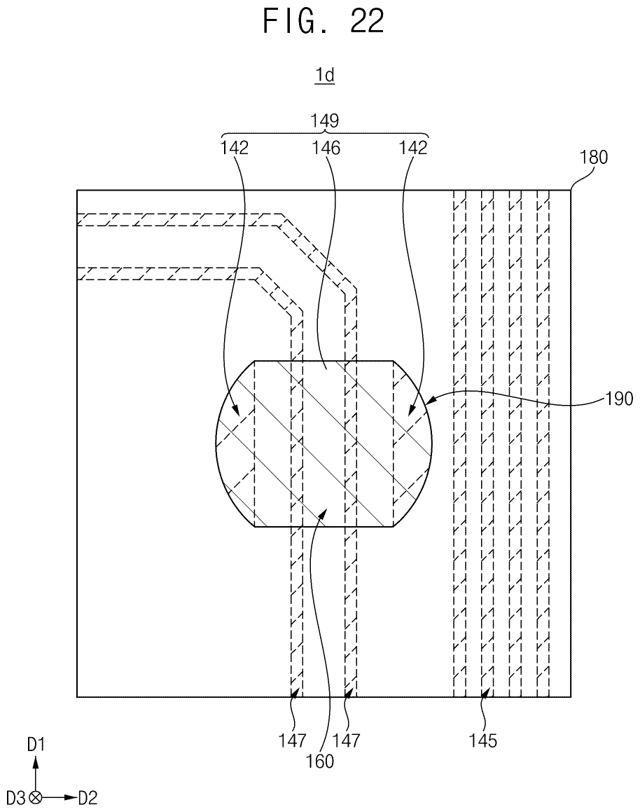

Referring to FIG. 22, the package substrate 1d may include ninth wirings 147, instead of the seventh wirings 144 extending in the first direction D1.

Each of the ninth wirings 147 may include a first portion extending in the first direction D1 through the second pad 149 via the fifth insulation layer 160 in a first region overlapping the second pad 149 in the third direction D3, a second portion extending in the second direction D2 in a second region not overlapping the second pad 149 in the third direction D3, and a third portion extending in a fourth direction having an acute angle with respect to the first and second directions D1, D2 in a third region between the first and second regions.

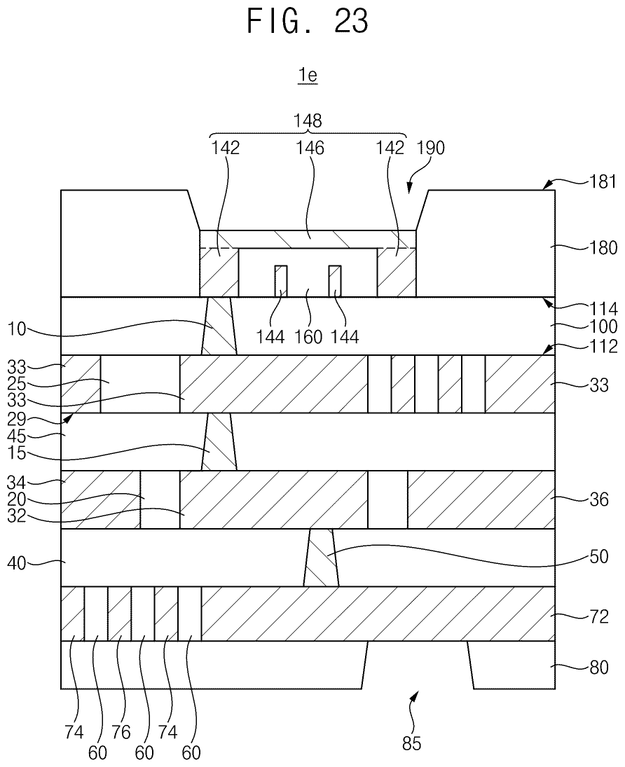

FIG. 23 is a cross-sectional view illustrating a package substrate 1e in accordance with some embodiments, which may correspond to FIG. 2. This package substrate 1e may be substantially the same as or similar to those illustrated with respect to FIGS. 1 and 2, except for including an additional wiring, an additional via and additional insulation layers, and thus repeated explanations are omitted herein.

Referring to FIG. 23, the package substrate 1e may further include sixth and seventh insulation layers 25, 45, and a tenth wiring 33 and a third via 15 extending through the sixth and seventh insulation layers 25, 45, respectively.

The sixth and seventh insulation layers 25, 45 may be stacked in the third direction D3 downwardly between the first and second insulation layers 100, 20, the tenth wiring 33 may contact a lower surface 9 of the first via 10, and the third via 15 may contact a lower surface 29 of the tenth wiring 33 and an upper surface 35 of the first wiring 32.

In some embodiments, the tenth wiring 33 may serve as a signal wiring.

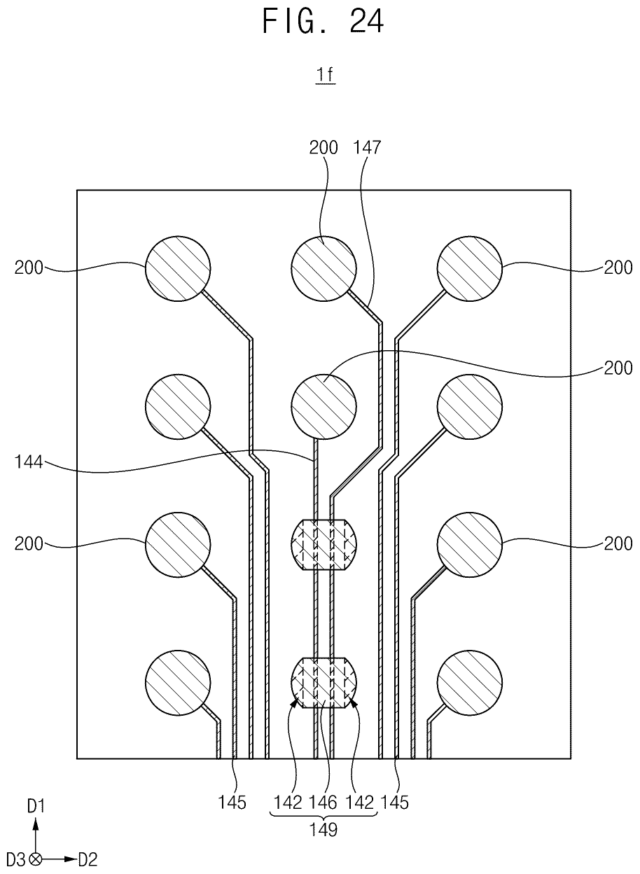

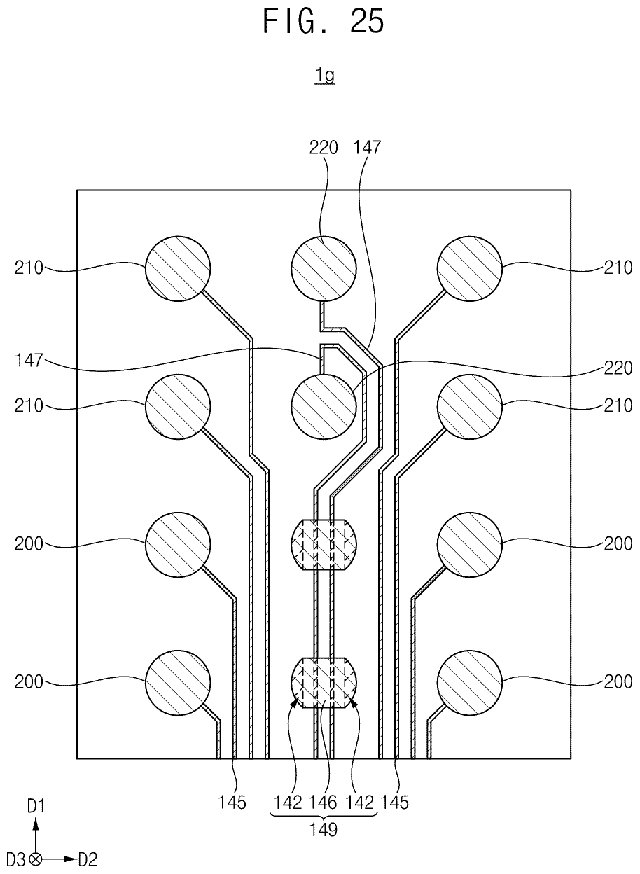

FIGS. 24 and 25 are plan views illustrating package substrates 1f, 1g in accordance with some embodiments, which may correspond to FIG. 14. These package substrates 1f, 1g may be substantially the same as or similar to those illustrated with respect to FIG. 14, except for including additional wirings and additional pads, and thus repeated explanations are omitted herein.

Referring to FIG. 24, the package substrate 1f may further include third pads 200 in addition to the second pad 149.

In some embodiments, some wirings at the same level as and contacting the third pad 200, e.g., seventh and ninth wirings 144, 147 may extend through the second pad 149. The ninth wiring 147 may detour a third pad 200 and extend through the second pad 149. In other words, the ninth wiring 147 may extend through the second pad 149 and may go around one of the third pads 200, for example, which contacts the seventh wiring 144.

In some embodiments, the second pad 149 may be connected to a ground wiring, while the third pad 200 may be connected to a signal wiring. The third pad 200 may have a shape of, e.g., a circle in a plan view.

Referring to FIG. 25, the package substrate 1g may further include third to fifth pads 200, 210, 220 in addition to the second pad 149.

In some embodiments, some wirings at the same level as and contacting the fifth pad 220, e.g., ninth wirings 147 may detour the fifth pad 220 and extend through the second pad 149. In other words, the ninth wiring 147 may extend through the second pad 149 and may go around a fifth pad 220.

In some embodiments, each of the second and fourth pads 149, 210 may be connected to a ground wiring, the third pad 200 may be connected to a signal wiring, and the fifth pad 220 may be connected to a high-speed signal wiring. In some embodiments, the ninth wirings 147 may form a differential pair, which may be side by side and which may transfer high-speed signals. The ninth wirings 147 transferring high-speed signals may extend through the second pad 149 so as to be shielded by the second pad 149, and thus the high-speed signals may be defect-free.

Each of the third to fifth pads 200, 210, 220 may have a shape of, e.g., a circle in a plan view.

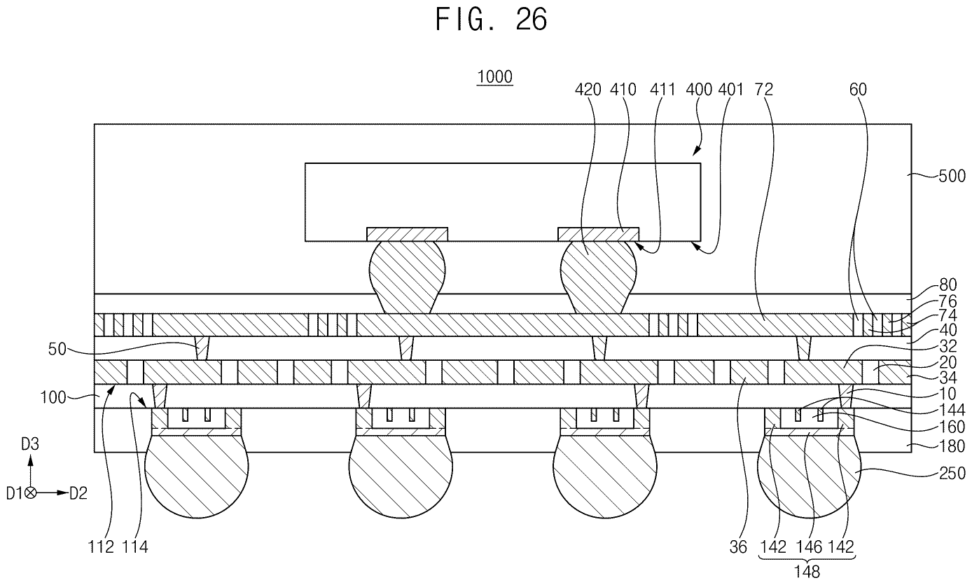

FIG. 26 is a cross-sectional view illustrating a semiconductor package 1000 in accordance with some embodiments. This semiconductor package 1000 may include the package substrate 1 of FIGS. 1 and 2, and thus repeated explanations are omitted herein. However, the semiconductor package 1000 may include one of the package substrates 1a-1g of FIG. 14 and FIGS. 20 to 25. FIG. 26 may be oriented such that the semiconductor package 1000 is rotated 180-degrees relative to the package substrate 1 in FIG. 2. Terms such as “upper” and “lower” may refer to the relative positions of components in the FIG. 2 orientation.

Referring to FIG. 26, the semiconductor package 1000 may include the package substrate 1, a semiconductor chip 400 on the first protective layer 80 included in the package substrate 1, a first conductive connection member 420 between the package substrate 1 and the semiconductor chip 400, a molding member 500 that is on the first protective layer 80 and covers the semiconductor chip 400 and the first conductive connection member 420, and a second conductive connection member 250 on an upper surface 181 of the second protective layer 180 included in the package substrate 1.

The semiconductor chip 400 may be a logic chip including a logic device or a memory chip including a memory device. A conductive pad 410 may be on, in, and/or part of an upper surface 401 of the semiconductor chip 400, and the first conductive connection member 420 may contact an upper surface 411 of the conductive pad 410 and a lower surface 71 of the portion of the fourth wiring 72 exposed by the first opening 85 in the first protective layer 80. The first conductive connection member 420 may include, e.g., a conductive bump or a conductive ball.

The molding member 500 may include, e.g., epoxy molding compound (EMC).

The second conductive connection member 250 may contact an upper surface 152 of a portion of the first pad 148 exposed by the fifth opening 190. The second conductive connection member 250 may include, e.g., a conductive bump or a conductive ball.

The foregoing is illustrative of some embodiments and is not to be construed as limiting thereof. Although a few some embodiments have been described, those skilled in the art will readily appreciate that many modifications are possible in some embodiments without materially departing from the novel teachings and advantages of the present invention. Accordingly, all such modifications are intended to be included within the scope of some embodiments as defined in the claims.

What is claimed is:

1. A package substrate comprising:
an insulation layer having first and second surfaces opposite to each other in a vertical direction;
a wiring on the first surface of the insulation layer;
a pad including:
first conductive layers at opposite sides, of the wiring on the first surface of the insulation layer; and
a second conductive layer contacting upper surfaces of the first conductive layers, spaced apart from an upper surface of the wiring, and overlapping at least a portion of the wiring in the vertical direction; and
a protective layer contacting the first surface of the insulation layer and covering a sidewall of the pad, the protective layer including solder resist (SR).

2. The package substrate according to claim 1, wherein each of the first conductive layers has a shape of an arch.

3. The package substrate according to claim 1, wherein each of the first conductive layers extends in a first direction substantially parallel to the first surface of the insulation layer.

4. The package substrate according to claim 3, wherein the second conductive layer extends in the first direction.

5. The package substrate according to claim 3, further comprising a plurality of wirings, each of which extends in the first direction, spaced apart from each other in a second direction, the second direction being substantially parallel to the first surface of the insulation layer and crossing the first direction, and the wiring being one of the plurality of wirings.

6. The package substrate according to claim 3, wherein the protective layer covers an upper surface of the second conductive layer and has an opening partially exposing the upper surface of the second conductive layer.

7. The package substrate according to claim 6, wherein the opening has a shape of a circle.

8. The package substrate according to claim 1, wherein the insulation layer is a first insulation layer, the package substrate further comprising a second insulation layer on the first surface of the first insulation layer and covering the upper surface and a sidewall of the wiring.

9. The package substrate according to claim 8, wherein the first conductive layers of the pad contacts a sidewall of the second insulation layer, and the second conductive layer of the pad contacts an upper surface of the second insulation layer.

10. The package substrate according to claim 1, wherein an upper surface of each of the first conductive layers is higher than the upper surface of the wiring.

11. The package substrate according to claim 1, wherein a width of each of the first conductive layers is substantially constant in the vertical direction.

12. The package substrate according to claim 1, wherein the insulation layer includes polypropylene glycol (PPG) or Ajinomoto build-up film (ABF).

13. The package substrate according to claim 1, wherein the insulation layer is a first insulation layer, the wiring is a first wiring, the protective layer is a first protective layer,
the package substrate further comprising:
a second insulation layer on the second surface of the first insulation layer;
a second wiring in the second insulation layer; and
a second protective layer on a lower surface of the second insulation layer, covering a lower surface of the second wiring, and having an opening partially exposing the lower surface of the second wiring.

14. A package substrate comprising:
an insulation layer having first and second surfaces opposite to each other in a vertical direction;
a wiring on the first surface of the insulation layer and extending in a first direction substantially parallel to the first surface of the insulation layer;
a pad including:
first conductive layers at opposite sides, of the wiring on the first surface of the insulation layer in a second direction, the second direction being substantially parallel to the first surface of the insulation layer and crossing the first direction, and each of the first conductive layers extending in the first direction; and
a second conductive layer contacting upper surfaces of the first conductive layers, extending in the first direction, and overlapping the wiring in the vertical direction; and
a protective layer on the first surface of the insulation layer and contacting a sidewall and an upper surface of the pad, the protective layer having an opening partially exposing the upper surface of the pad and including solder resist (SR).

15. The package substrate according to claim 14, further comprising a plurality of wirings spaced apart from each other in the second direction, the wiring being one of the plurality of wirings.

16. The package substrate according to claim 14, wherein each of the first conductive layers has a shape of an arch.

17. The package substrate according to claim 14, wherein the insulation layer is a first insulation layer,
the package substrate further comprising a second insulation layer on the first surface of the first insulation layer and covering the upper surface and a sidewall of the wiring.

18. The package substrate according to claim 17, wherein the first conductive layers of the pad contacts a sidewall of the second insulation layer, and the second conductive layer of the pad contacts an upper surface of the second insulation layer.

19. A semiconductor package comprising:
a package substrate including:
first insulation layer having first and second surfaces opposite to each other in a vertical direction;
a first wiring on the first surface of the first insulation layer;
a pad including:
first conductive layers at opposite sides, of the first wiring on the first surface of the first insulation layer; and
a second conductive layer contacting upper surfaces of the first conductive layers, spaced apart from an upper surface of the first wiring, and overlapping at least a portion of the first wiring in the vertical direction; and
a first protective layer contacting the first surface of the first insulation layer and covering a sidewall of the pad, the first protective layer including solder resist (SR);
a second insulation layer on the second surface of the first insulation layer;
a second wiring in the second insulation layer; and
a second protective layer on the second insulation layer, covering a lower surface of the second wiring, and having an opening exposing a portion of the lower surface of the second wiring;
a semiconductor chip on the package substrate;
a first conductive connection member contacting the exposed portion of the lower surface of the second wiring and an upper surface of the semiconductor chip; and
a second conductive connection member contacting an upper surface of the pad.

20. The package substrate according to claim 19, further comprising a plurality of first wirings spaced apart from each other between the first conductive layers, the first wiring being one of the plurality of first wirings.
